(19) United States
(12) Patent Application Publication
(10) Pub. No.: US 2026/0096276 A1
(43) Pub. Date: Apr. 2, 2026

(54) DETECTION DEVICE

(71) Applicant: Japan Display Inc., Tokyo (JP)

(72) Inventors: Kazuhide MOCHIZUKI, Tokyo (JP); Masahiro TADA, Tokyo (JP)

(21) Appl. No.: 19/412,257

(22) Filed: Dec. 8, 2025

Related U.S. Application Data
(63) Continuation of application No. PCT/JP2024/016776, filed on May 1, 2024.

(30) Foreign Application Priority Data
Jun. 14, 2023 (JP) 2023-097917

(51) Int. Cl. H10K 30/88; H10K 39/32

(52) U.S. Cl. CPC H10K 30/88; H10K 39/32

(57) ABSTRACT

A detection device includes: a substrate; an inorganic insulating film, an organic insulating film, and a barrier film stacked on the substrate; an organic optical sensor including a lower electrode, a lower buffer layer, an active layer, an upper buffer layer, and an upper electrode; and a first inorganic sealing film. The inorganic insulating film, the organic insulating film, the barrier film, the organic optical sensor, and the first inorganic sealing film are stacked in a detection area in this order. The inorganic insulating film, the organic insulating film, the barrier film, and the first inorganic sealing film are stacked in a peripheral area in this order. On an outer edge side of the substrate, side surfaces of the organic insulating film and the inorganic insulating film are located closer to the detection area than a side surface of the substrate and covered by the first inorganic sealing film.

### CROSS-REFERENCE TO RELATED APPLICATION

This application claims the benefit of priority from Japanese Patent Application No. 2023-097917 filed on Jun. 14, 2023 and International Patent Application No.

PCT/JP2024/016776 filed on May 1, 2024, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPDs)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

In a detection device including the OPDs, if moisture enters a detection area provided with the OPDs from outside the detection device, the detection accuracy may decrease.

For the foregoing reasons, there is a need for a detection device capable of reducing moisture entering the detection area.

### SUMMARY

According to an aspect, a detection device includes: a substrate; an inorganic insulating film, an organic insulating film, and a barrier film that are stacked on the substrate; an organic optical sensor in which a lower electrode, a lower buffer layer, an active layer, an upper buffer layer, and an upper electrode are stacked in a detection area of the substrate in the order listed; and a first inorganic sealing film that covers the organic optical sensor. The inorganic insulating film, the organic insulating film, the barrier film, the organic optical sensor, and the first inorganic sealing film are stacked in the detection area in the order listed. The inorganic insulating film, the organic insulating film, the barrier film, and the first inorganic sealing film are stacked in a peripheral area outside the detection area in the order listed. On an outer edge side of the substrate, a side surface of the organic insulating film and a side surface of the inorganic insulating film are located closer to the detection area than a side surface of the substrate is. The side surface of the organic insulating film and the side surface of the inorganic insulating film are covered by the first inorganic sealing film.

According to an aspect, a detection device includes: a substrate; an inorganic insulating film, an organic insulating film, and a barrier film that are stacked on the substrate; an organic optical sensor in which a lower electrode, a lower buffer layer, an active layer, an upper buffer layer, and an upper electrode are stacked in a detection area of the substrate in the order listed; and a first inorganic sealing film that covers the organic optical sensor. The inorganic insulating film, the organic insulating film, the barrier film, the organic optical sensor, and the first inorganic sealing film are stacked in the detection area in the order listed. The inorganic insulating film, the organic insulating film, the barrier film, and the first inorganic sealing film are stacked in a peripheral area outside the detection area in the order listed. The detection device comprises a plurality of grooves in the peripheral area that are formed on an upper surface of the organic insulating film and extend along an outer edge of the substrate in plan view.

### BRIEF DESCRIPTION OF THE DRAWINGS

FIG. 1 is a plan view schematically illustrating a detection device according to an embodiment of the present disclosure;

FIG. 2 is a block diagram illustrating a configuration example of the detection device according to the embodiment;

FIG. 3 is a circuit diagram illustrating the detection device according to the embodiment;

FIG. 4 is a plan view schematically illustrating a plurality of photodiodes in a detection area and a plurality of grooves in a peripheral area;

FIG. 5 is a sectional view taken along V-V′ in FIG. 4;

FIG. 6 is a sectional view taken along VI-VI′ in FIG. 4;

FIG. 7 is a sectional view schematically illustrating a detection device according to a comparative example;

FIG. 8 is a plan view schematically illustrating the detection device before outline cutting; and

FIG. 9 is a sectional view taken along IX-IX′ in FIG. 8.

### DETAILED DESCRIPTION

The following describes a mode (embodiment) for carrying out the present disclosure in detail with reference to the drawings. The present disclosure is not limited to the description of the embodiment given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### Embodiment

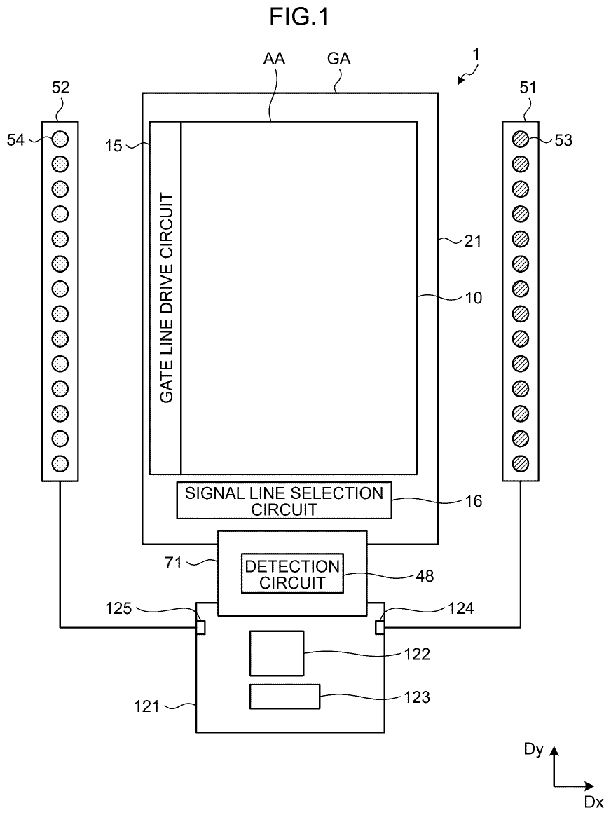

FIG. 1 is a plan view schematically illustrating a detection device according to an embodiment of the present disclosure. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

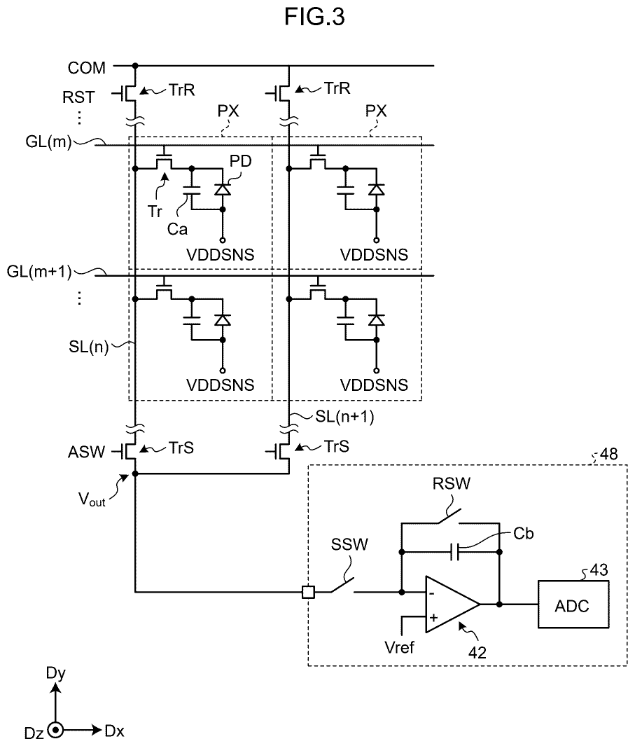

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

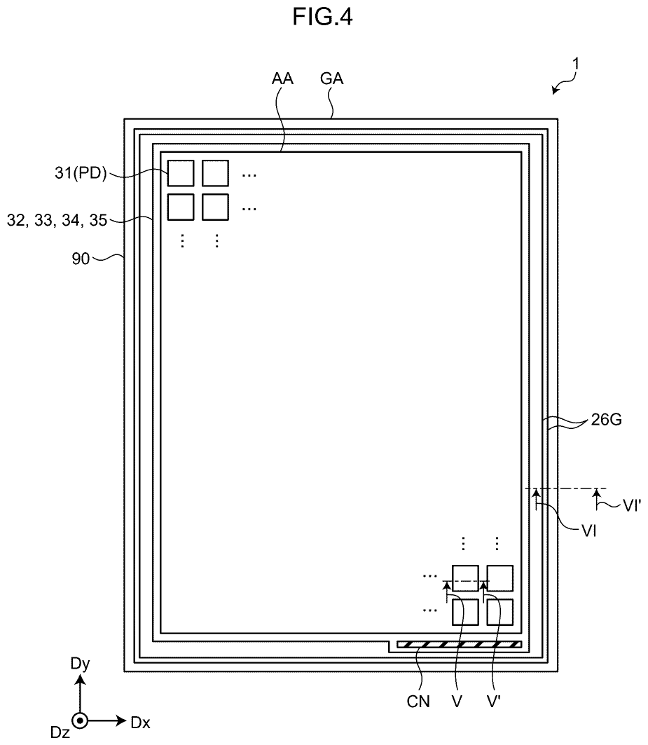

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edge of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is one direction in a plane parallel to the substrate 21. The second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed along a direction orthogonal to the substrate 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled, through respective terminals 124 and 125 provided on the control substrate 121, to the control circuit 122 and the power supply circuit 123.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect a fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

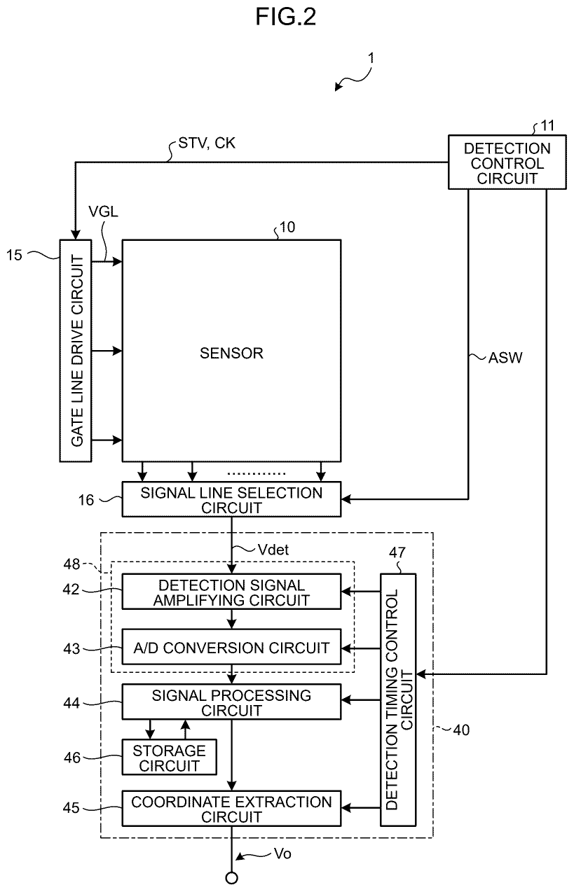

FIG. 2 is a block diagram illustrating a configuration example of the detection device according to the embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. Through this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signal Vdet of the photodiode PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 so as to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can also detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is an area surrounded by the gate lines GL and the signal lines SL.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the amount of the light irradiating the photodiode PD for each sensor pixel PX.

In the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the embodiment, the same signal as the sensor reference voltage COM is supplied as the reference potential (Vref) voltage. The control circuit 122 (refer to FIG. 1) calculates the difference between the detection signal Vdet when light is emitted and the detection signal Vdet when light is not emitted, as each of the sensor output voltages Vo. The detection signal amplifying circuit 42 includes a capacitive element Cb and a reset switch RSW. In a reset period, the reset switch RSW is turned on to reset the electric charge of the capacitive element Cb.

The drive transistor Tr is not limited to an n-type TFT and may be configured as a p-type TFT. The pixel circuit of the sensor pixel PX illustrated in FIG. 3 is merely exemplary. The sensor pixel PX may be provided with a plurality of transistors corresponding to each of the photodiodes PD.

The following describes a configuration of the photodiodes PD, a sealing film 90, and a plurality of grooves 26G, with reference to FIGS. 4 to 6. FIG. 4 is a plan view schematically illustrating the photodiodes in the detection area and the grooves in the peripheral area.

As illustrated in FIG. 4, the photodiodes PD (organic optical sensors) are arranged in a matrix in a row-column configuration in the detection area AA. The photodiodes PD each include a lower electrode 31, a lower buffer layer 32, an active layer 33, an upper buffer layer 34, and an upper electrode 35. A plurality of the lower electrodes 31 are provided so as to be separated for the each of the photodiodes PD and are arranged in a matrix having a row-column configuration in the detection area AA. The lower buffer layer 32, the active layer 33, the upper buffer layer 34, and the upper electrode 35 are continuously provided across the photodiodes PD and provided across the entire detection area AA. A portion of the upper electrode 35 extends to the peripheral area GA, is coupled to a contact CN, and is electrically coupled to external circuits (such as the control circuit 122 and the power supply circuit 123 (refer to FIG. 1)) via wiring of the substrate 21.

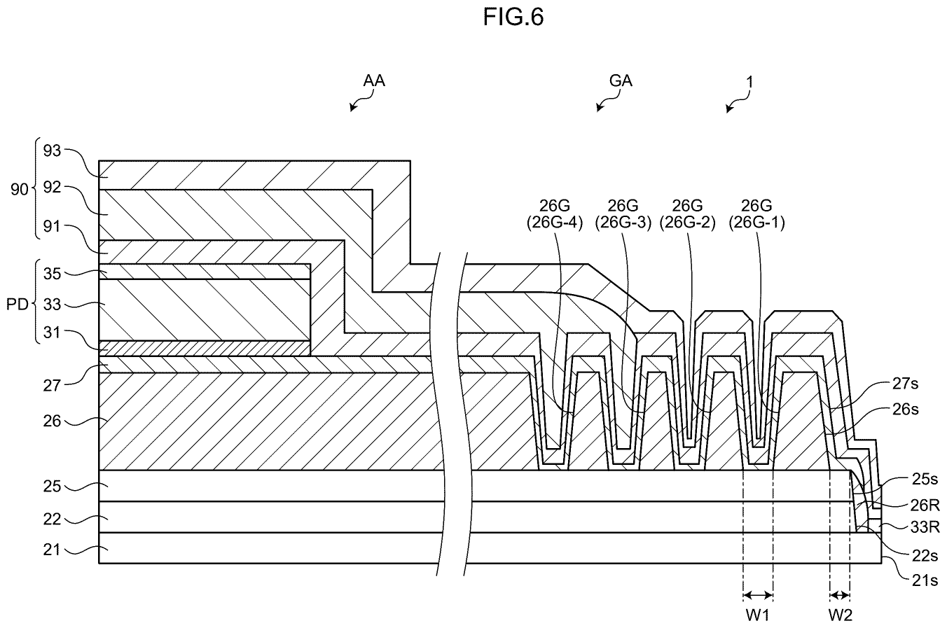

The detection device 1 includes the sealing film 90 covering the photodiodes PD. The sealing film 90 is provided across the detection area AA and the peripheral area GA and extends to the outer edge side of the substrate 21. The grooves 26G are provided in the peripheral area GA. The sealing film 90 is provided so as to cover the grooves 26G. The sealing film 90 and the grooves 26G can reduce water entering the detection area AA from the outer edge side of the substrate 21. A detailed configuration of the sealing film 90 and the grooves 26G will be described later with reference to FIG. 6.

The grooves 26G are provided so as to surround the outer periphery of the detection area AA. Each of the grooves 26G has a continuous frame shape. However, FIG. 4 is merely schematically illustrated, and the grooves 26G may be omitted in some portions along the outer periphery of the detection area AA. The wiring substrate 71 illustrated in FIG. 1 may be coupled to a terminal provided on the substrate 21 on the outer side of the grooves 26G, or may be coupled to a terminal provided on the substrate 21 through an opening provided in the sealing film 90.

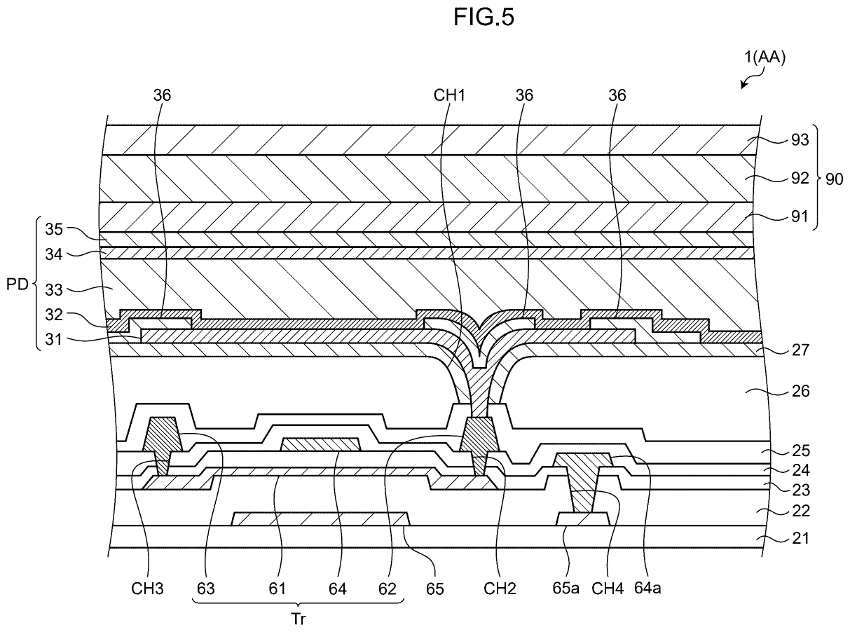

The following describes a multilayered structure of the photodiodes PD and the sealing film 90 of the detection device 1. FIG. 5 is a sectional view taken along V-V′ in FIG. 4.

In the following description, a direction from the substrate 21 toward the sealing film 90 in a direction orthogonal to a surface of the substrate 21 is referred to as “upper side” or simply “above”. A direction from the sealing film 90 toward the substrate 21 is referred to as “lower side” or simply “below”.

As illustrated in FIG. 5, the detection device 1 includes the substrate 21, the drive transistor Tr, a plurality of inorganic insulating films (undercoat film 22, gate insulating film 23, interlayer insulating film 24, and overlaid insulating film 25), an organic insulating film 26, a barrier film 27, the photodiode PD, and the sealing film 90. The inorganic insulating films (undercoat film 22, gate insulating film 23, interlayer insulating film 24, and overlaid insulating film 25), the organic insulating film 26, the barrier film 27, the photodiode PD, and the sealing film 90 (first inorganic sealing film 91, organic sealing film 92, and second inorganic sealing film 93) are stacked in this order on the substrate 21 in the detection area AA.

The substrate 21 is an insulating substrate formed of a film-like resin. The drive transistor Tr is provided in an area overlapping the lower electrode 31 of the photodiode PD. Specifically, the drive transistor Tr includes a semiconductor layer 61, a source electrode 62, a drain electrode 63, and a gate electrode 64.

A light-blocking film 65 is provided on the substrate 21. The light-blocking film 65 is provided between the semiconductor layer 61 and the substrate 21. The light-blocking film 65 reduces light entering from the substrate 21 side to a channel region of the semiconductor layer 61.

The undercoat film 22 is provided on the substrate 21 so as to cover the light-blocking film 65. The undercoat film 22 is formed, for example, of an inorganic insulating film such as a silicon nitride film or a silicon oxide film. The configuration of the undercoat film 22 is not limited to that illustrated in FIG. 5. For example, the undercoat film 22 may be a multilayered film having two, three, or more stacked layers.

The drive transistor Tr is provided above the substrate 21. The semiconductor layer 61 is provided on the undercoat film 22. The gate insulating film 23 is provided on the undercoat film 22 so as to cover the semiconductor layer 61. The gate insulating film 23 is, for example, an inorganic insulating film such as a silicon oxide film. The gate electrode 64 is provided on the gate insulating film 23.

In the example illustrated in FIG. 5, the drive transistor Tr has a top-gate structure. However, the drive transistor Tr is not limited thereto and may have a bottom-gate structure or a dual-gate structure in which the gate electrodes 64 are provided on the upper and lower sides of the semiconductor layer 61.

The interlayer insulating film 24 is provided on the gate insulating film 23 so as to cover the gate electrode 64. The interlayer insulating film 24 has, for example, a multilayered structure of a silicon nitride film and a silicon oxide film. The source electrode 62 and the drain electrode 63 are provided on the interlayer insulating film 24. The source electrode 62 is coupled to a source region of the semiconductor layer 61 through a contact hole CH2 provided through the gate insulating film 23 and the interlayer insulating film 24. The drain electrode 63 is coupled to a drain region of the semiconductor layer 61 through a contact hole CH3 provided through the gate insulating film 23 and the interlayer insulating film 24. The overlaid insulating film 25 is provided on the interlayer insulating film 24 so as to cover the source electrode 62 and the drain electrode 63.

Coupling wiring 64a is provided in the same layer as the gate electrode 64. The coupling wiring 64a is electrically coupled to the gate electrode 64. Coupling wiring 65a is provided in the same layer as the light-blocking film 65. The coupling wiring 65a is electrically coupled to the light-blocking film 65. The coupling wiring 64a is coupled to the coupling wiring 65a through a contact hole CH4 penetrating the undercoat film 22 and the gate insulating film 23. With this configuration, the light-blocking film 65 is electrically coupled to the gate electrode 64 via the coupling wiring 64a and 65a and is supplied with the same potential as that of the gate electrode 64.

The organic insulating film 26 is provided on the overlaid insulating film 25 so as to cover the source electrode 62 and the drain electrode 63 of the drive transistor Tr. The organic insulating film 26 is a planarizing film formed of an organic insulating material. In the present embodiment, a contact hole CH1 in the organic insulating film 26 is provided in an area thereof overlapping the source electrode 62. The lower electrode 31 of the photodiode PD is electrically coupled to the source electrode 62 at the bottom of the contact hole CH1.

The detection device 1 may have a configuration in which the overlaid insulating film 25 among the inorganic insulating films (undercoat film 22, gate insulating film 23, interlayer insulating film 24, and overlaid insulating film 25) is not provided. In that case, the organic insulating film 26 is provided on the interlayer insulating film 24 so as to cover the source electrode 62 and the drain electrode 63.

The barrier film 27 is provided on the organic insulating film 26. The barrier film 27 is formed, for example, of an inorganic insulating material such as a silicon nitride (SiN) film.

The photodiode PD is provided on the barrier film 27. In the photodiode PD, the lower electrode 31, the lower buffer layer 32, the active layer 33, the upper buffer layer 34, and the upper electrode 35 are stacked in this order in the direction orthogonal to the substrate 21. The photodiode PD of the present embodiment is an organic photodiode (OPD) using an organic semiconductor as the active layer 33.

The lower electrode 31 is formed, for example, of a light-transmitting conductive material such as indium tin oxide (ITO). The lower buffer layer 32, the active layer 33, the upper buffer layer 34, and the upper electrode 35 are provided continuously across the photodiodes PD. Specifically, the lower buffer layer 32, the active layer 33, the upper buffer layer 34, and the upper electrode 35 are provided so as to overlap the lower electrodes 31, and provided so as to overlap the barrier film 27 located between the adjacent lower electrodes 31.

An insulating film 36 is provided so as to cover the peripheries of the lower electrodes 31. The insulating film 36 is provided so as to cover the contact hole CH1 and covers the lower electrode 31 in an area overlapping the contact hole CH1. The insulating film 36 insulates between the lower electrodes 31 of the adjacent photodiodes PD. Even if a step break occurs in the lower buffer layer 32 in the area overlapping the contact hole CH1, the occurrence of a short circuit between the active layer 33 and the lower electrode 31 can be prevented or reduced because the insulating film 36 is provided. In the present embodiment, the insulating film 36 is formed of an inorganic insulating material, such as a silicon nitride (SiN) film or a silicon oxide (SiO₂) film.

The active layer 33 changes in characteristics (for example, voltage-current characteristics and resistance value) depending on light emitted thereto. An organic material is used as a material of the active layer 33. Specifically, the active layer 33 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI. The active layer 33 is not limited to the bulk heterostructure and may have a positive-intrinsic-negative (PIN) structure.

The lower buffer layer 32 and the upper buffer layer 34 are provided to facilitate holes and electrons generated in the active layer 33 to reach the lower electrode 31 or the upper electrode 35. The lower buffer layer 32 is provided between the lower electrode 31 and the active layer 33 and is in direct contact with the lower electrode 31 and the active layer 33. The lower buffer layer 32 is provided between the adjacent lower electrodes 31 so as to cover the barrier film 27.

The upper buffer layer 34 is provided between the active layer 33 and the upper electrode 35 and is in direct contact with the active layer 33 and the upper electrode 35. The upper electrode 35 is provided on the upper buffer layer 34. The upper electrode 35 is formed, for example, of a light-transmitting conductive material such as ITO or indium zinc oxide (IZO). The upper electrode 35 is, however, not limited thereto, and may be formed, for example, of a non-light-transmitting conductive material such as silver (Ag).

In the present embodiment, the lower electrode 31 is a cathode electrode of the photodiode PD, and the upper electrode 35 is an anode electrode of the photodiode PD. In this case, the lower buffer layer 32 is an electron transport layer and the upper buffer layer 34 is a hole transport layer. Polyethylenimine ethoxylated (PEIE) is used as a material of the electron transport layer. The material of the hole transport layer is a metal oxide layer. Tungsten oxide (WO₃), molybdenum oxide, or the like is used as the metal oxide layer.

The lower electrode 31 may be the anode electrode of the photodiode PD, and the upper electrode 35 may be the cathode electrode of the photodiode PD. In that case, the lower buffer layer 32 may be a hole transport layer, and the upper buffer layer 34 may be an electron transport layer.

The sealing film 90 is provided on the upper electrode 35. Specifically, in the sealing film 90, the first inorganic sealing film 91, the organic sealing film 92, and the second inorganic sealing film 93 are stacked in this order on the upper electrode 35. The first inorganic sealing film 91 and the second inorganic sealing film 93 are each formed of an inorganic film such as a silicon nitride film or an aluminum oxide film. The organic sealing film 92 is formed of a resin film of an acrylic resin or the like. The sealing film 90 well seals the photodiodes PD, and thus can reduce water entering the photodiodes PD from the upper surface side thereof.

The following describes the configuration of the sealing film 90 and the grooves 26G in the peripheral area GA. FIG. 6 is a sectional view taken along VI-VI′ in FIG. 4. To facilitate understanding, FIG. 6 illustrates the multilayered configuration of the inorganic insulating films, the organic insulating film 26, the barrier film 27, the photodiode PD, and the sealing film 90 in the detection area AA as well as the configuration of the peripheral area GA. The configuration of the detection area AA in FIG. 6 is the same as that described with reference to FIG. 5 and will not be described again.

Among the inorganic insulating films (undercoat film 22, gate insulating film 23, interlayer insulating film 24, and overlaid insulating film 25), FIG. 6 illustrates the undercoat film 22 in the bottom layer and the overlaid insulating film 25 in the top layer and does not illustrate the gate insulating film 23 and the interlayer insulating film 24. In the following description, the overlaid insulating film 25 in the top layer among the inorganic insulating films will be mentioned, but the term “overlaid insulating film 25” may refer to the multilayered film from the undercoat film 22 to the overlaid insulating film 25.

As illustrated in FIG. 6, the overlaid insulating film 25, the organic insulating film 26, the barrier film 27, and the sealing film 90 are provided across the detection area AA and the peripheral area GA. That is, the overlaid insulating film 25 (inorganic insulating films), the organic insulating film 26, the barrier film 27, the photodiodes PD (organic optical sensors), and the sealing film 90 (first inorganic sealing film 91, organic sealing film 92, and second inorganic sealing film 93) are stacked in the detection area AA in this order. The overlaid insulating film 25, the organic insulating film 26, the barrier film 27, and the sealing film 90 (first inorganic sealing film 91, organic sealing film 92, and second inorganic sealing film 93) are stacked in this order in the peripheral area GA outside the detection area AA.

In the present embodiment, the peripheral area GA has the grooves 26G formed on the upper surface of the organic insulating film 26. As described above with reference to FIG. 4, the grooves 26G extend along the outer edge of the substrate 21 in plan view. In the example illustrated in FIG. 6, four grooves 26G-1, 26G-2, 26G-3, and 26G-4 are arranged from the outer edge side of the substrate 21 toward the detection area AA. In the following description, the four grooves 26G-1, 26G-2, 26G-3, and 26G-4 are simply referred to as “grooves 26G” when need not be distinguished from one another. The number of the grooves 26G is not limited to four and may be one to three, or five or more.

Each of the grooves 26G penetrates the organic insulating film 26 from the top surface to the bottom surface, and the overlaid insulating film 25 forms the bottom of the groove 26G. The barrier film 27 is provided along the top surface of the organic insulating film 26, and the side surfaces and the bottoms of the grooves 26G. The overlaid insulating film 25 is in direct contact with the barrier film 27 at the bottoms of the grooves 26G. A width W1 of each of the grooves 26G is equal to or larger than 50 μm. This configuration can improve the adhesion between the overlaid insulating film 25 and the barrier film 27 at the bottom of the groove 26G. The width W1 of the groove 26G is the width W1 of the bottom of the groove 26G and is a length of a portion where the overlaid insulating film 25 is in contact with the barrier film 27 between the adjacent portions of the organic insulating film 26.

The sealing film 90 is provided across areas overlapping the grooves 26G in the peripheral area GA. In the sealing film 90, an outer-edge end of the organic sealing film 92 is located further inward (closer to the detection area AA) than outer-edge ends of the first and the second inorganic sealing films 91 and 93. The second inorganic sealing film 93 of the sealing film 90 is provided so as to cover the organic sealing film 92 and is provided in direct contact with the first inorganic sealing film 91 on the outer side of the organic sealing film 92.

Among the grooves 26G, the grooves 26G-3 and 26G-4 closer to the detection area AA are covered by the first inorganic sealing film 91, the organic sealing film 92, and the second inorganic sealing film 93. That is, the overlaid insulating film 25, the barrier film 27, and the sealing film 90 (first inorganic sealing film 91, organic sealing film 92, and second inorganic sealing film 93) are stacked in this order, in an area overlapping the grooves 26G-3 and 26G-4. The first inorganic sealing film 91 of the sealing film 90 is provided along the top surface of the organic insulating film 26, and the side surfaces and the bottoms of the grooves 26G-3 and 26G-4, so as to cover the barrier film 27. The organic sealing film 92 of the sealing film 90 is provided so as to fill the grooves 26G-3 and 26G-4.

The other grooves 26G-1 and 26G-2 closer to the outer edge of the substrate 21 are covered by the first and the second inorganic sealing films 91 and 93. The inorganic insulating films (undercoat film 22 to overlaid insulating film 25), the barrier film 27, the first inorganic sealing film 91, and the second inorganic sealing film 93 are stacked in this order, in an area overlapping the grooves 26G-1 and 26G-2 closer to the outer edge of the substrate 21. The first and the second inorganic sealing films 91 and 93 of the sealing film 90 are provided along the top surface of the organic insulating film 26, and the side surfaces and the bottoms of the grooves 26G-1 and 26G-2, so as to cover the barrier film 27.

Since the grooves 26G of the organic insulating film 26 and the sealing film 90 are provided in this way in the peripheral area GA, an area provided with more than one inorganic insulating film and not provided with the organic films (organic insulating film 26 and organic sealing film 92) is formed at least in the grooves 26G-1 and 26G-2. Thus, in the grooves 26G-1 and 26G-2, a structure to block a path through which moisture enters between the outer edge of the substrate 21 and the detection area AA is formed.

In the present embodiment, since the grooves 26G are provided in the organic insulating film 26, the length along the surface of the organic insulating film 26, specifically, the total length along the top surface of the organic insulating film 26 and the side surfaces and the bottoms of the grooves 26G is longer than in a case where the grooves 26G are not provided. As a result, the path through which moisture enters from the outer edge of the substrate 21 to the detection area AA increases, so that moisture entering the detection area AA can be reduced.

As illustrated in FIG. 6, in the detection device 1 of the present embodiment, on the outer edge side of the substrate 21, a side surface 26s of the organic insulating film 26 and a side surface 25s of the overlaid insulating film 25 (including side surface 22s of undercoat film 22 and side surface 25s of overlaid insulating film 25) are located closer to the detection area AA then a side surface 21s of the substrate 21 is. The side surface 26s of the organic insulating film 26 is located closer to the detection area AA than the side surface 25s of the overlaid insulating film 25 is.

In other words, steps are formed along the top surface and the side surface 26s of the organic insulating film 26, the top surface and the side surface 25s of the overlaid insulating film 25, and the top surface and the side surface 21s of the substrate 21. On the outer edge side of the substrate 21, the top surface of the overlaid insulating film 25 has an area not provided with the organic insulating film 26 between the side surface 25s and the side surface 26s of the organic insulating film 26. The top surface of the substrate 21 has an area not provided with the inorganic insulating films (undercoat film 22 to overlaid insulating film 25) between the side surface 21s and the side surface 22s of the undercoat film 22.

The barrier film 27 is in contact with the overlaid insulating film 25 (inorganic insulating films) on the outer edge side of the substrate 21. More specifically, the barrier film 27 is provided so as to cover the top surface and the side surface 26s of the organic insulating film 26 on the outer edge side of the substrate 21. The barrier film 27 is further in contact with the top surface of the overlaid insulating film 25 between the side surface 26s of the organic insulating film 26 and the side surface 25s of the overlaid insulating film 25. The barrier film 27 and the overlaid insulating film 25 are provided in direct contact with each other on the outer edge side of the substrate 21. A width W2 of a portion where the barrier film 27 is in contact with the overlaid insulating film 25 between the side surface 26s of the organic insulating film 26 and the side surface 25s of the overlaid insulating film 25 is 3μm or larger. Thus, the adhesion between the barrier film 27 and the overlaid insulating film 25 on the outer edge side of the substrate 21 can be ensured. Such a configuration forms the structure to block the path through which moisture enters from the outer edge side of the substrate 21.

The first and the second inorganic sealing films 91 and 93 of the sealing film 90 are provided so as to extend to the outer edge side of the substrate 21 beyond the groove 26G-1 and so as to overlap the barrier film 27. In other words, on the outer edge side of the substrate 21, the top surface and the side surface 26s of the organic insulating film 26 and the side surface 25s of the overlaid insulating film 25 are covered by the first and the second inorganic sealing films 91 and 93.

On the outer edge side of the substrate 21, a residue 26R of the organic insulating film 26 and a residue 33R of the active layer 33 of the photodiode PD are formed on the side surface 25s of the overlaid insulating film 25 (including the side surface 22s of the undercoat film 22 to the side surface 25s of the overlaid insulating film 25).

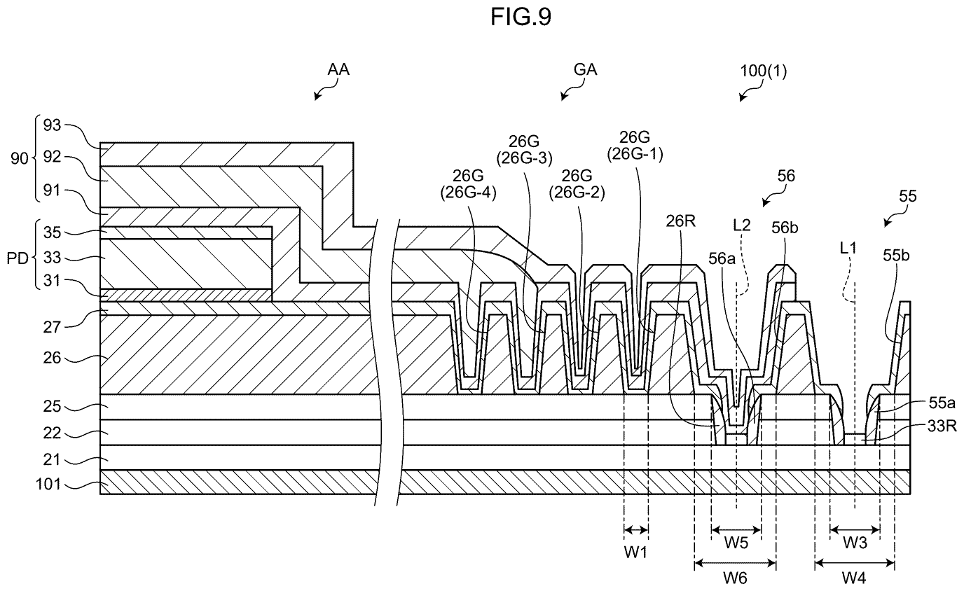

The residue 26R of the organic insulating film 26 and the residue 33R of the active layer 33 are formed in a manufacturing process of the substrate 21. The residue 26R of the organic insulating film 26 and the residue 33R of the active layer 33 will be described later with reference to FIG. 9.

In the present embodiment, the side surface 26s of the organic insulating film 26 is located closer to the detection area AA than the side surface 25s of the overlaid insulating film 25, and the residue 26R of the organic insulating film 26 is formed away from the organic insulating film 26 on the upper side of the overlaid insulating film 25. The barrier film 27 is provided so as to cover at least a portion of the residue 26R of the organic insulating film 26. Furthermore, the residue 26R of the organic insulating film 26 and the residue 33R of the active layer 33 are covered by the first and the second inorganic sealing films 91 and 93.

Such a configuration separates the residue 26R of the organic insulating film 26 and the residue 33R of the active layer 33 from the organic insulating film 26. Therefore, a path through which moisture enters is not formed via the residue 26R of the organic insulating film 26 and the residue 33R of the active layer 33 on the outer edge side of the substrate 21. As a result, the detection device 1 can reduce moisture entering from the outer edge side of the substrate 21 even when the residue 26R of the organic insulating film 26 and the residue 33R of the active layer 33 are provided.

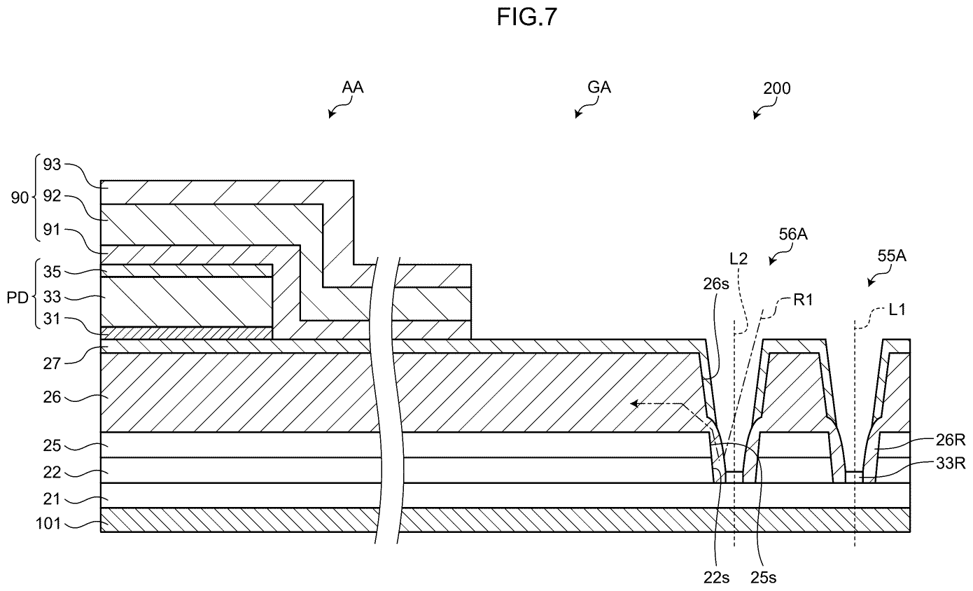

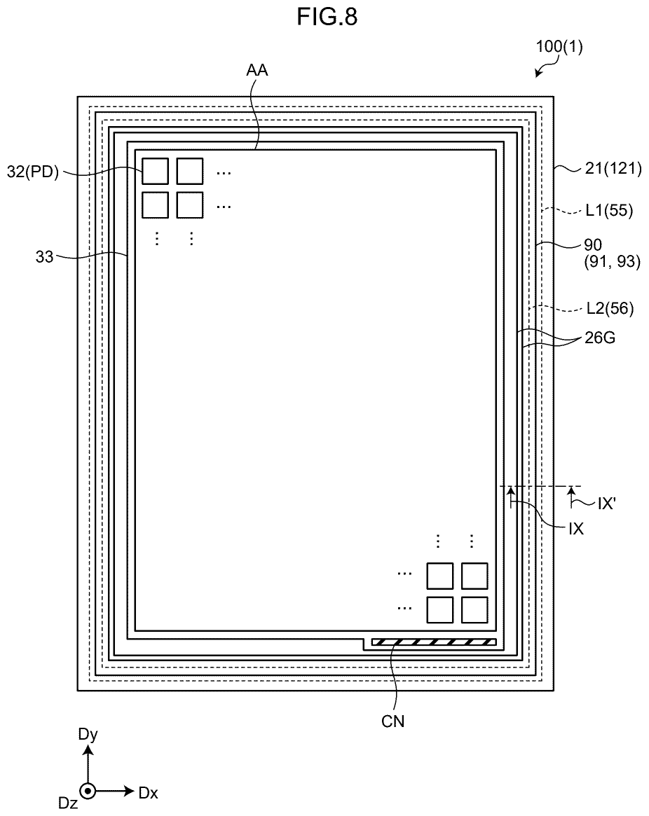

The following describes a detection device 200 according to a comparative example, with reference to FIG. 7. FIG. 7 is a sectional view schematically illustrating the detection device according to the comparative example. In the detection device 200 according to the comparative example illustrated in FIG. 7, the configuration of the detection area AA is the same as that of the detection device 1 according to the embodiment. The same components as those described in the embodiment described above are denoted by the same reference numerals, and the description thereof will not be repeated. FIG. 9 illustrates the detection device before outline cutting. The detection device of the comparative example is formed by performing a cutting process along an outline cut line L1 and an outline cut line L2. The outline cut lines L1 and L2 will be described with reference to FIGS. 8 and 9.

In the detection device 200 illustrated in FIG. 7, the top surface of the organic insulating film 26 is formed flat in the peripheral area GA, and the grooves 26G are not formed. On the outer edge side of the substrate 21, the side surface 26s of the organic insulating film 26 and the side surfaces of the inorganic insulating films (from the side surface 22s of the undercoat film 22 to the side surface 25s of the overlaid insulating film 25) form the same plane. That is, in the comparative example, no step is formed along the organic insulating film 26 and the overlaid insulating film 25 on the outer edge side of the substrate 21.

In this case, grooves 55A and 56A provided in areas overlapping the outline cut lines L1 and L2 are formed deeply, and a lower portion of the side surface 26s of the organic insulating film 26 may not be covered by the barrier film 27. In addition, if the residue 26R of the organic insulating film 26 and the residue 33R of the active layer 33 are present in the grooves 55A and 56A, at least one of the residue 26R of the organic insulating film 26 and the residue 33R of the active layer 33 may be formed in contact with the side surface 26s of the organic insulating film 26. As a result, as indicated by an arrow of a long dashed short dashed line, an entry path R1 of external moisture is formed on the outer edge side of the substrate 21. The external moisture may enter along the entry path R1, pass through the residue 26R of the organic insulating film 26 and the side surface 26s of the organic insulating film 26, travel inside the organic insulating film 26, and then enter the detection area AA side.

In contrast, in the present embodiment, as described with reference to FIG. 6, the side surface 26s of the organic insulating film 26 and the side surface 25s of the overlaid insulating film 25 are covered by the first and the second inorganic sealing films 91 and 93. In addition, on the outer edge side of the substrate 21, the barrier film 27 is in contact with the top surface of the overlaid insulating film 25 between the side surface 26s of the organic insulating film 26 and the side surface 25s of the overlaid insulating film 25. This configuration forms the structure to block the moisture entry path on the outer edge side of the substrate 21, allowing the detection device 1 to reduce the water entering from the outer edge side of the substrate 21.

The following describes a method for manufacturing the detection device 1. FIG. 8 is a plan view schematically illustrating the detection device before the outline cutting. FIG. 9 is a sectional view taken along IX-IX′ in FIG. 8. As illustrated in FIGS. 8 and 9, in a detection device 100 before the outline cutting, the substrate 21 is bonded onto a support substrate 101 made of glass or the like. The detection device 1 of the present embodiment is formed by cutting the detection device 100 before the outline cutting along the outline cut lines L1 and L2.

In the detection device 100 before the outline cutting, a groove 55 is provided at a location overlapping the outline cut line L1, and a groove 56 is provided at a location overlapping the outline cut line L2. The grooves 55 and 56 are each formed by removing the inorganic insulating films (undercoat film 22 to overlaid insulating film 25) and the organic insulating film 26 on the substrate 21.

The following describes a manufacturing process of the detection device 100 before the outline cutting. First, in the manufacturing process of the detection device 100 before the outline cutting, grooves 55a and 56a are formed in the inorganic insulating films (undercoat film 22 to overlaid insulating film 25) in areas overlapping the outline cut lines L1 and L2, respectively, on the substrate 21. This can inhibit cracking of the inorganic insulating films during the outline cutting.

The organic insulating film 26 is formed by being applied onto the entire surface of the detection area AA and the peripheral area GA so as to cover the overlaid insulating film 25 and the grooves 55a and 56a. Then, the organic insulating film 26 is patterned by etching or the like, thus forming the grooves 26G in the peripheral area GA of the substrate 21, and also forming grooves 55b and 56b in the areas overlapping the outline cut lines L1 and L2, respectively. At this time, part of the organic insulating film 26 formed by being applied into the grooves 55a and 56b of the inorganic insulating films (undercoat film 22 to overlaid insulating film 25) may not be removed and may remain as the residue 26R.

In the present embodiment, in the groove 55 formed at the location overlapping the outline cut line L1, a width W4 of the groove 55b formed in the organic insulating film 26 is larger than a width W3 of the groove 55a of the inorganic insulating films (undercoat film 22 to overlaid insulating film 25). In the groove 56 formed at the location overlapping the outline cut line L2, a width W6 of the groove 56b formed in the organic insulating film 26 is larger than a width W5 of the groove 56a of the inorganic insulating films (undercoat film 22 to overlaid insulating film 25). As a result, a step is formed between the organic insulating film 26 and the overlaid insulating film 25 in each of the grooves 55 and 56.

Then, the barrier film 27 is formed, and the photodiode PD is formed on the barrier film 27. The active layer 33 of the photodiode PD is formed by being applied onto the entire surface of the detection area AA and the peripheral area GA so as to cover the barrier film 27 and the grooves 55 and 56. Then, the active layer 33 in the peripheral area GA is removed by etching or the like. At this time, part of the active layer 33 in the grooves 55 and 56 may not be removed and may remain as the residue 33R.

Then, the sealing film 90 is formed so as to cover the photodiode PD. In the sealing film 90, the outer-edge end of the organic sealing film 92 is patterned so as to be located further inward (closer to the detection area AA) than the outer-edge ends of the first and the second inorganic sealing films 91 and 93.

The detection device 100 before the outline cutting is first cut along the outline cut line L1 in an area overlapping the bottom of the groove 55, by die cutting, for example. The detection device 100 before the outline cutting is then cut along the outline cut line L2 in an area overlapping the bottom of the groove 56 and positioned inward with respect to the outline cut line L1, by a laser process, for example. Thus, the detection device 1 is formed.

Through the process described above, in the detection device 1, the configuration on the outer edge side of the substrate 21 is formed correspondingly to the shape of the groove 56 of the detection device 100 before the outline cutting. Specifically, as illustrated in FIG. 6, the step between the organic insulating film 26 and the overlaid insulating film 25 is formed on the outer edge side of the substrate 21. The residue 26R of the organic insulating film 26 and the residue 33R of the active layer 33 may be formed on the side surface 25s of the overlaid insulating film 25 on the outer edge side of the substrate 21.

The detection device 100 before the outline cutting illustrated in FIGS. 8 and 9 and the method for manufacturing the same are merely exemplary, and can be changed as appropriate. For example, the groove 55 formed at the location overlapping the outline cut line L1 has the same shape as the groove 56 formed at the location overlapping the outline cut line L2, but the present disclosure is not limited thereto. The widths W3 and W4 of the groove 55 may differ from the widths W5 and W6 of the groove 56.

Although the above has described the configuration in which the residue 26R of the organic insulating film 26 and the residue 33R of the active layer 33 are formed with reference to FIGS. 7 and 9, the configuration is not limited thereto. One of the residue 26R of the organic insulating film 26 and the residue 33R of the active layer 33 may be formed on the outer edge side of the substrate 21. That is, on the outer edge side of the substrate 21, the residue 26R of the organic insulating film 26 may be provided on the side surface 25s of the overlaid insulating film 25 (including the side surface 22s of the undercoat film 22 to the side surface 25s of the overlaid insulating film 25), and the residue 26R of the organic insulating film 26 may be covered by the first and the second inorganic sealing films 91 and 93. Alternatively, the residue 26R of the organic insulating film 26 and the residue 33R of the active layer 33 may not be provided.

While the preferred embodiment of the present disclosure has been described above, the present disclosure is not limited to such an embodiment. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiment described above and the modifications thereof.

What is claimed is:

1. A detection device comprising:
a substrate;
an inorganic insulating film, an organic insulating film, and a barrier film that are stacked on the substrate;
an organic optical sensor in which a lower electrode, a lower buffer layer, an active layer, an upper buffer layer, and an upper electrode are stacked in a detection area of the substrate in the order listed; and
a first inorganic sealing film that covers the organic optical sensor, wherein
the inorganic insulating film, the organic insulating film, the barrier film, the organic optical sensor, and the first inorganic sealing film are stacked in the detection area in the order listed,
the inorganic insulating film, the organic insulating film, the barrier film, and the first inorganic sealing film are stacked in a peripheral area outside the detection area in the order listed,
on an outer edge side of the substrate, a side surface of the organic insulating film and a side surface of the inorganic insulating film are located closer to the detection area than a side surface of the substrate is, and
the side surface of the organic insulating film and the side surface of the inorganic insulating film are covered by the first inorganic sealing film.

2. The detection device according to claim 1, wherein the barrier film is in contact with the inorganic insulating film on the outer edge side of the substrate.

3. The detection device according to claim 1, wherein
the side surface of the organic insulating film is located closer to the detection area than the side surface of the inorganic insulating film is, and
the barrier film is in contact with an upper surface of the inorganic insulating film between the side surface of the organic insulating film and the side surface of the inorganic insulating film.

4. The detection device according to claim 3, wherein a portion where the barrier film is in contact with the inorganic insulating film between the side surface of the organic insulating film and the side surface of the inorganic insulating film is 3 μm or more in width.

5. The detection device according to claim 1, wherein
at least one of a residue of the organic insulating film or a residue of the organic optical sensor is provided on the side surface of the inorganic insulating film, and
at least one of the residue of the organic insulating film or the residue of the organic optical sensor is covered by the first inorganic sealing film.

6. The detection device according to claim 1, wherein
the residue of the organic insulating film is provided on the side surface of the inorganic insulating film, and
the barrier film covers at least a portion of the residue of the organic insulating film.

7. The detection device according to claim 1, comprising an organic sealing film and a second inorganic sealing film that are stacked on the first inorganic sealing film.

8. The detection device according to claim 1, comprising a plurality of grooves in the peripheral area that are formed on an upper surface of the organic insulating film and extend along an outer edge of the substrate in plan view.

9. The detection device according to claim 8, wherein each of the grooves is 50μm or more in width.

10. The detection device according to claim 8, comprising an organic sealing film and a second inorganic sealing film that are stacked on the first inorganic sealing film, wherein
one of the grooves closer to the detection area is covered by the first inorganic sealing film, the organic sealing film, and the second inorganic sealing film, and
another one of the grooves closer to the outer edge of the substrate is covered by the first inorganic sealing film and the second inorganic sealing film.

11. A detection device comprising:
a substrate;
an inorganic insulating film, an organic insulating film, and a barrier film that are stacked on the substrate;
an organic optical sensor in which a lower electrode, a lower buffer layer, an active layer, an upper buffer layer, and an upper electrode are stacked in a detection area of the substrate in the order listed; and
a first inorganic sealing film that covers the organic optical sensor, wherein
the inorganic insulating film, the organic insulating film, the barrier film, the organic optical sensor, and the first inorganic sealing film are stacked in the detection area in the order listed,
the inorganic insulating film, the organic insulating film, the barrier film, and the first inorganic sealing film are stacked in a peripheral area outside the detection area in the order listed, and
the detection device comprises a plurality of grooves in the peripheral area that are formed on an upper surface of the organic insulating film and extend along an outer edge of the substrate in plan view.

12. The detection device according to claim 11, wherein the inorganic insulating film is in direct contact with the barrier film at bottoms of the grooves.

13. The detection device according to claim 11, comprising an organic sealing film and a second inorganic sealing film that are stacked on the first inorganic sealing film.

14. The detection device according to claim 13, wherein
one of the grooves closer to the detection area is covered by the first inorganic sealing film, the organic sealing film, and the second inorganic sealing film, and
another one of the grooves closer to the outer edge of the substrate is covered by the first inorganic sealing film and the second inorganic sealing film.
